(19) United States
(12) Patent Application Publication
(10) Pub. No.: US 2024/0199412 A1
(43) Pub. Date: Jun. 20, 2024

(54) METHOD AND SYSTEM FOR FABRICATING A MEMS DEVICE CAP

(71) Applicant: InvenSense, Inc., San Jose, CA (US)

(72) Inventor: Camillo Pilla, Castiglione del Lago (IT)

(21) Appl. No.: 18/380,131

(22) Filed: Oct. 13, 2023

Related U.S. Application Data
(60) Provisional application No. 63/433,684, filed on Dec. 19, 2022.

(51) Int. Cl. B81B 7/00; B81C 1/00

(52) U.S. Cl. CPC B81B 7/008; B81C 1/00246; B81B 2201/0235; B81B 2201/0242; B81C 2203/035

(57) ABSTRACT

A device includes a first die and a second die. The first die and the second die are stacked and form a monolithic die. A first side of the first die faces a first side of the second die. The second die comprises an electrical connection within its periphery and on a side other than the first side of the second die. The electrical connection exposes the second die to an environment outside of the monolithic die. The electrical connection is configured to facilitate electrical connection between the second die of the monolithic die and an electronic component that is external to the monolithic die.

### RELATED APPLICATIONS

The instant application is a non-provisional application and claims the benefit and priority to a provisional application No. 63/433,684 that was filed on Dec. 19, 2022, which is incorporated herein in its entirety.

### BACKGROUND

MEMS (“micro-electro-mechanical systems”) are a class of devices that are fabricated using semiconductor-like processes and exhibit mechanical characteristics. For example, MEMS devices may include the ability to move or deform. In many cases, but not always, MEMS interact with electrical signals. A MEMS device may refer to a semiconductor device that is implemented as a micro-electro-mechanical system. A MEMS device includes mechanical elements and may optionally include electronics (e.g., electronics for sensing).

In recent years, some have created a monolithic chip design that includes a MEMS die integrated with a complementary metal oxide semiconductor (CMOS) die. Generally, the bonding pad on a CMOS should be exposed in order to route electrical signals to components outsides of the monolithic chip (die). In order to expose the bonding pad on the CMOS die, the CMOS die and the MEMS die should be staggered (leaving the bonding pad on the CMOS exposed) before forming a monolithic chip, which requires high precision and very little room for error when forming a monolithic die (i.e., alignment of CMOS die and MEMS die). Alternatively, if the CMOS die and the MEMS die are stacked without being staggered, then the bond pad on the CMOS is subsequently exposed by removing a portion of the MEMS die (by sawing it as an example). Unfortunately, removing a portion of the MEMS die is not only a manual process but it also requires high precision and applies unnecessary mechanical stress on the monolithic die.

Additionally, even if the bonding pad on the CMOS die is exposed successfully, wire bonding the CMOS die to a component outside of the monolithic die causes additional stress on the monolithic die. For example, wire bonding may result in additional stress on the MEMS die due to resonance frequency of ultrasound when wire bonding occurs.

### SUMMARY

Accordingly, a need has arisen to fabricate a monolithic die (comprising a MEMS die and a CMOS die) in such a fashion to enable the CMOS die of the monolithic die to make electrical connection with electrical components external to the monolithic die without having to stagger the alignment of the CMOS die to the MEMS die (when forming the monolithic die in order to expose the bonding pad on the CMOS die). Moreover, a need has arisen to fabricate a monolithic die (comprising a MEMS die and a CMOS die) in such a fashion to enable the CMOS die of the monolithic die to make electrical connection with electrical components external to the monolithic die without requiring a portion of the MEMS die to be removed (i.e., in order to expose a bond pad on the CMOS die of the monolithic die). Furthermore, a need has arisen to fabricate a monolithic die (comprising a MEMS die and a CMOS die) while enabling the CMOS die of the monolithic die to make electrical connection with electrical components external to the monolithic die without imposing additional stress on the monolithic die caused during wire bonding process by eliminating the wire bonding process all together.

In some embodiments, a method includes forming a plurality of CMOS dice on a CMOS wafer, wherein each CMOS die of the plurality of CMOS dice includes a plurality of TSVs (e.g., cube shaped, circular shaped, etc.) associated therewith and positioned on a periphery of its associated CMOS die. The method further includes forming a plurality of MEMS dice on a MEMS wafer. The method also includes forming a monolithic wafer by stacking the CMOS wafer and the MEMS wafer, wherein the monolithic wafer comprises a plurality of monolithic dice, wherein each monolithic die of the plurality of monolithic dice comprises a CMOS die and a MEMS die that are stacked on top of one another forming a monolithic die. It is appreciated that according to some embodiments, the method further includes separating a first monolithic die from a second monolithic die of the monolithic wafer by cutting through a scribe region between the first monolithic die and the second monolithic die. The first monolithic die comprises a first MEMS die and a first CMOS die and wherein the second monolithic die comprises a second MEMS die and a second CMOS die. The separating exposes at least one or more TSVs of the plurality of TSVs of the first CMOS die to an environment outside of the first monolithic die. The separating exposes at least one or more TSVs of the plurality of TSVs of the second CMOS die to the environment outside of the second monolithic die. The at least one or more TSVs of the plurality of TSVs of the first CMOS is configured to facilitate electrical connection between the first CMOS die of the first monolithic die and an electronic component that is external to the first monolithic die.

It is appreciated that the at least one or more TSVs of the plurality of TSVs of the second CMOS is configured to facilitate electrical connection between the second CMOS die of the second monolithic die and another electronic component that is separate from the second monolithic die and is positioned outside of the second monolithic die. According to some embodiments, the first MEMS die comprises a first MEMS cap layer that is coupled to a first MEMS device layer. The first MEMS device layer includes movable structures including a proof mass. The first MEMS cap layer forms at least a cavity when coupled to the first MEMS device layer. The first MEMS die is a sensor for measuring gyro or acceleration. In some embodiments, the method further includes coupling a substrate that includes the electronic component to the first monolithic die, wherein the electrical connection between the first CMOS die and the electrical component is formed through a solder ball formed between the at least one or more TSVs of the plurality of TSVs on the first CMOS die and a connection pad of the substrate. It is appreciated that in some embodiments the forming the monolithic wafer includes eutectic bonding the CMOS wafer to the MEMS wafer.

In some embodiments, a device includes a first die and a second die. The first die and the second die are stacked and form a monolithic die (e.g., eutectic bonding the first die to the second die), wherein a first side of the first die faces a first side of the second die. The second die comprises an electrical connection within its periphery and on a side other than the first side of the second die, wherein the electrical connection exposes the second die to an environment outside of the monolithic die. The electrical connection is configured to facilitate electrical connection between the second die of the monolithic die and an electronic component that is external to the monolithic die.

It is appreciated that in some embodiments the first die is a MEMS die and the second die is a CMOS die, wherein the MEMS die comprises a MEMS cap layer that is coupled to a MEMS device layer. In some embodiments, the MEMS device layer comprises movable structures including a proof mass. In one nonlimiting example, the MEMS cap layer forms at least a cavity when coupled to the MEMS device layer. The MEMS die may be a sensor for measuring gyro or acceleration. In some embodiments, the device may further include a substrate comprising the electronic component, wherein the electrical connection on the second die is a plurality of TSVs (e.g., cube shaped, etc.), and wherein the electrical connection between the second die and the electrical component is formed through a solder ball formed between at least one TSV of the plurality of TSVs on the second die and a connection pad of the substrate.

A monolithic device may include a MEMS die and a CMOS die bonded to the MEMS die forming a single integrated die. The CMOS die comprises a plurality of TSVs (e.g., cube shaped, etc.) positioned on an outer edge of the CMOS die and is exposed to an environment outside of the single integrated die. The plurality of TSVs is configured to facilitate electrical connection between the CMOS die and an electronic component that is external to the single integrated die.

These and other features and advantages will be apparent from a reading of the following detailed description.

### BRIEF DESCRIPTION OF DRAWINGS

FIG. 1 shows a fabricated monolithic die comprising a MEMS die and a CMOS die according to one aspect of the present embodiments.

FIG. 2 shows a fabricated CMOS die according to one aspect of the present embodiments.

FIG. 3 shows a fabricated monolithic die comprising a MEMS die and a CMOS die according to one aspect of the present embodiments.

FIG. 4A shows a CMOS wafer according to one aspect of the present embodiments.

FIG. 4B shows a fabricated monolithic wafer comprising a MEMS die and a CMOS die according to one aspect of the present embodiments.

FIG. 5 shows a fabricated monolithic die coupled to an external circuitry according to one aspect of the present embodiments.

FIG. 6 shows a method flow for fabricating a CMOS die according to one aspect of the present embodiments.

### DESCRIPTION

Before various embodiments are described in greater detail, it should be understood that the embodiments are not limiting, as elements in such embodiments may vary. It should likewise be understood that a particular embodiment described and/or illustrated herein has elements which may be readily separated from the particular embodiment and optionally combined with any of several other embodiments or substituted for elements in any of several other embodiments described herein.

It should also be understood that the terminology used herein is for the purpose of describing the certain concepts, and the terminology is not intended to be limiting. Unless defined otherwise, all technical and scientific terms used herein have the same meaning as commonly understood in the art to which the embodiments pertain.

Unless indicated otherwise, ordinal numbers (e.g., first, second, third, etc.) are used to distinguish or identify different elements or steps in a group of elements or steps, and do not supply a serial or numerical limitation on the elements or steps of the embodiments thereof. For example, “first,” “second,” and “third” elements or steps need not necessarily appear in that order, and the embodiments thereof need not necessarily be limited to three elements or steps. It should also be understood that, unless indicated otherwise, any labels such as “left,” “right,” “front,” “back,” “top,” “middle,” “bottom,” “beside,” “forward,” “reverse,” “overlying,” “underlying,” “up,” “down,” or other similar terms such as “upper,” “lower,” “above,” “below,” “under,” “between,” “over,” “vertical,” “horizontal,” “proximal,” “distal,” and the like are used for convenience and are not intended to imply, for example, any particular fixed location, orientation, or direction. Instead, such labels are used to reflect, for example, relative location, orientation, or directions. It should also be understood that the singular forms of “a,” “an,” and “the” include plural references unless the context clearly dictates otherwise.

Terms such as “over,” “overlying,” “above,” “under,” etc., are understood to refer to elements that may be in direct contact or may have other elements in-between. For example, two layers may be in overlying contact, wherein one layer is over another layer and the two layers physically contact. In another example, two layers may be separated by one or more layers, wherein a first layer is over a second layer and one or more intermediate layers are between the first and second layers, such that the first and second layers do not physically contact.

A MEMS die may include a MEMS device layer coupled to a cap layer. The MEMS device layer may commonly be referred to as the actuator layer with movable structures, e.g., mechanical elements, proof mass, etc. It is appreciated that a MEMS die may optionally include electronics (e.g., electronics for sensing). The cap layer coupled to the MEMS device layer may form one or more cavities for housing moveable structures of gyro, accelerometer, magnetometers, pressure sensors, etc. It is appreciated that the MEMS layer may be coupled to a semiconductor layer, e.g., a CMOS layer, to form a MEMS die.

As discussed above, monolithic die comprising a CMOS die and a MEMS die have been developed. For example, the monolithic die may be formed by coupling the MEMS die (on top) to the CMOS die (at the bottom). In this example, the active side of the CMOS die is its top surface facing the MEMS die. As such, when a monolithic die is formed the active side of the CMOS die is covered (unexposed) by the MEMS die. In order to expose the CMOS die (partially) in order to facilitate electrical connection between the CMOS die and an external circuitry (e.g., electrical component), either the CMOS die and the MEMS die have to be staggered such that when the monolithic die is formed the bonding pad of the CMOS die is exposed and not covered by MEMS die, or if covered by the MEMS die then a portion of the MEMS die is to be (subsequent to the formation of the monolithic die) removed in order to expose the bonding pad on the CMOS die to make the electrical connection from the active side of the CMOS die to an external circuitry. As discussed above, aligning (whether in staggered fashion or not) requires high precision. If the monolithic die is formed in a non-staggered fashion then a portion of the MEMS die needs to be removed in order to expose the bonding pad on the active surface of the CMOS die. Additionally, making wire bonding connection from the CMOS die to an external circuitry may cause stress due to resonance frequency of ultrasound when wire bonding occurs.

Accordingly, a need has arisen to fabricate a monolithic die (comprising a MEMS die and a CMOS die) without having to remove a portion of the MEMS die and/or without causing additional stress of resonance frequency of ultrasound during the wire bonding process. In other words, a need has arisen to fabricate the CMOS die in such a manner to move the electrical contacts from the active side (top of the CMOS), that would necessitate staggering the CMOS die and the MEMS die or that would necessitate removing a portion of the MEMS die if the monolithic die is formed without staggering the alignment of the CMOS die and the MEMS die, to a side of the CMOS die that does not require the alignment in staggering fashion or that does not require removing a portion of the MEMS die. For example, the electrical contacts of the CMOS die may be moved to its periphery (outer edges of the CMOS die) by forming one or more through silicon vias (TSVs) that go through the bottom surface of the CMOS, as opposed to the top surface of the active side. As such, the CMOS die may be connected to an external circuitry by using one or more TSVs that expose the bottom surface of the CMOS die to the external environment. In some embodiments, the TSVs may be formed on the edges of the CMOS die enabling the CMOS die to contact an external circuitry from its side and/or bottom surface, as opposed to its active surface (i.e., top surface facing the MEMS die). It is appreciated that the TSVs may be metalized once formed in order to facilitate the electrical connection to the external circuitry, as needed.

It is appreciated that a CMOS die and a MEMS die may be coupled to one another (e.g., stacked on top of one another) as a single block (i.e., die) to form a monolithic die. As one nonlimiting example, a CMOS die and a MEMS die may be integrated as a single monolithic die by eutecticly bonding (e.g., via an Aluminum layer and a Germanium layer) the CMOS die and the MEMS die that are stacked on top of one another (e.g., CMOS die at the bottom and the MEMS die at the top).

It is appreciated that the embodiments and the monolithic die is described with respect to a MEMS die and a CMOS die for illustrative purposes but should not be construed as limiting the scope of the embodiments. For example, it is appreciated that two CMOS dice may be stacked on top of one another to form a monolithic die instead of a MEMS die and a CMOS die. As another example, a monolithic die may be formed by using a die and a cover structure (that may not necessarily be a die but rather a film or other type of structure such as a packaging structure). Furthermore, it is appreciated that the electrical connection configured to electrically connect the CMOS die to the external circuitry is described as TSVs for illustrative purposes and should not be construed as limiting the scope of the embodiments. For example, a wire bonding or flip chip connection positioned on the periphery and side of the CMOS die may facilitate the electrical connection without having to stagger the two dice of the monolithic die or without having to remove a portion of a die within the monolithic die.

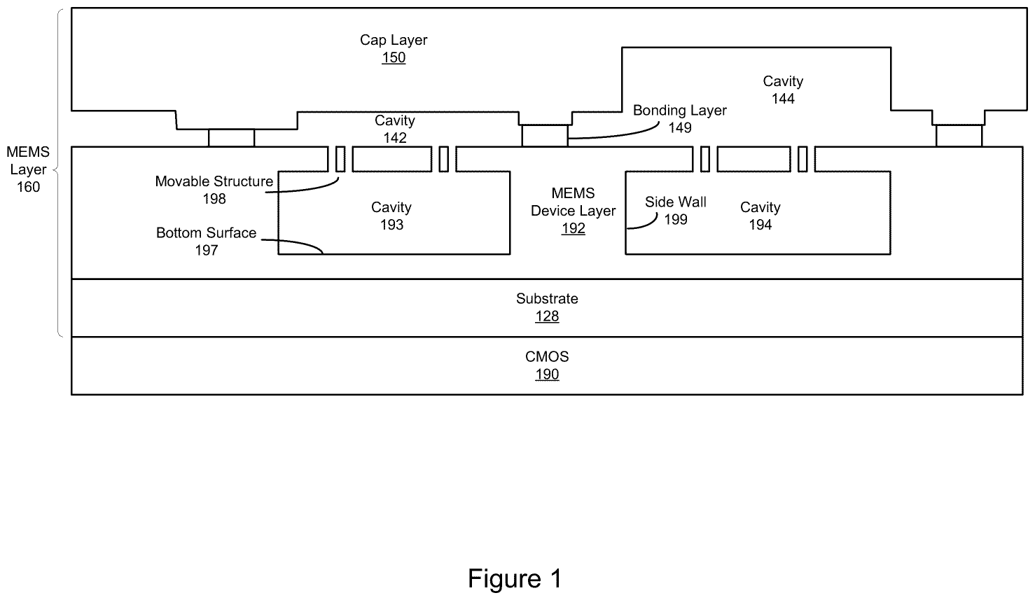

Referring now to FIG. 1, a fabricated monolithic die comprising a MEMS die and a CMOS die according to one aspect of the present embodiments is shown. The monolithic die in this nonlimiting example includes a MEMS layer 160 (also referred to as a MEMS die) that is stacked on top of a CMOS 190 die and coupled thereto. In one nonlimiting example, the MEMS layer 160 and the CMOS 190 die are integrated in such a fashion to form a single monolithic die, e.g., by eutecticly bonding the MEMS layer 160 to the CMOS 190 die. In one nonlimiting example, the MEMS layer 160 may be eutecticly bonded to the CMOS 190 die through heating a layer of germanium/aluminum layer on the MEMS layer 160 and the CMOS 190 die.

The MEMS layer 160 may include a MEMS device layer 192 that is coupled to (i.e., bonded to) a cap layer 150 that forms cavities 142 and 144 for gyro-sensing and accelerometer sensing respectively, as an example. In some embodiments, the cap layer 150 is bonded (e.g., eutecticly bonded) via a bonding layer 149 (e.g., Ge, AlCu, Al, etc.) to the MEMS device layer 192. In an example, eutectic bonding layer 149 can be formed by heating germanium/aluminum layer from the cap layer 150 and the MEMS device layer 192. The eutectic bond provides a hermetic seal to cavity 142 and cavity 144. The eutectic bond provides electrical connection from cap layer 150 to the MEMS device layer 192. The cap layer 150 may include an outgassing substance (not shown) used for damping purposes in accelerometer cavity 142 with high cavity pressure. An upper surface of the cap layer 150 cavity 144 may be lined with a getter material, e.g., Ti, TiN, etc., to stabilize the cavity 144 pressure, making it suitable for gyro measurements. The monolithic layer comprising the MEMS device layer 192 and the cap layer 150 may be coupled to a substrate 128, e.g., silicon substrate.

It is appreciated that the MEMS device layer 192 may be formed from a substrate, e.g., a p-silicon substrate or an n-silicon substrate. The MEMS device layer 192 forms the actuator layer of the MEMS layer 160. It is appreciated that the MEMS device layer 192 may include one or more cavities, e.g., cavity 193 and 194 in this example corresponding to gyro-sensing and accelerometer sensing respectively. According to some nonlimiting examples, a layer of intermetal dielectric (not shown here) such as SiO₂ or SiN may be formed over the p-silicon substrate of the MEMS device layer 192. For example, a layer of intermetal dielectric may coat the side walls 199 of the cavity 193 and/or 194. The cavity 193 and/or 194 in the MEMS device layer 192 may also include a bumpstop (not shown here) to stop the proof mass from contacting the circuitry underneath. It is also appreciated that cavity 193 and/or 194 may include one or more electrodes (not shown) at the bottom surface 197 of respective cavities 193 and/or 194 (forming one plate of a capacitor). In some nonlimiting examples, a second electrode may be formed on the movable structures 198, e.g., proof mass, that is positioned on top of the cavities 193 and/or 194 facing the bottom surface 197 of the cavities 193 and/or 194 of the MEMS device layer 192 in order to form the second plate of the capacitor. A stimuli causes the movable structures 198 to be displaced causing one electrode to move with respect to the fixed electrode at the bottom surface 197 of the cavities 193 and/or 194, thereby detecting a different charge and therefore sensing gyro or acceleration in this example.

It is appreciated that the MEMS layer 160 may make electrical contact with the CMOS 190 die via a bond pad positioned on a top surface of the MEMS device layer 192 or through a bond pad positioned on its back and through the substrate 128.

It is appreciated that the embodiments and the monolithic die is described with respect to a MEMS die and a CMOS die for illustrative purposes but should not be construed as limiting the scope of the embodiments. For example, it is appreciated that two CMOS dice may be stacked on top of one another to form a monolithic die instead of a MEMS die and a CMOS die.

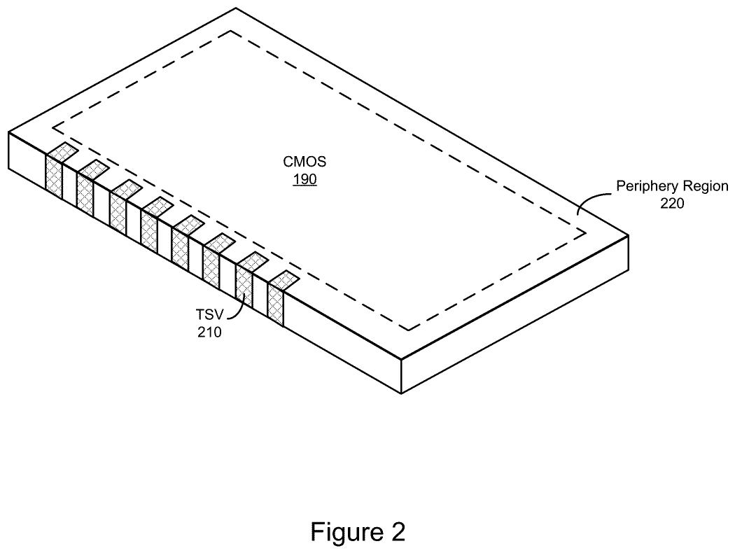

Referring now to FIG. 2, a fabricated CMOS die according to one aspect of the present embodiments is shown. A CMOS 190 die includes a periphery region 220. The periphery region 220 may be on the outer edges of the CMOS 190 die. One or more TSVs 210 may be formed on one or more sides of the CMOS 190 die. The TSVs 210 may be metalized in order to enable the CMOS 190 die to make electrical connections with external circuitries (circuitry external to the monolithic die after the MEMS die and the CMOS 190 die are integrated as a single die). According to some embodiments, the TSVs 210 may be formed only on one side of the CMOS 190 for illustrative purposes and should not be construed as limiting the scope of the embodiments. For example, the TSVs 210 may be formed on two sides, three sides, or four sides of the CMOS 190 die. In this example, the TSVs 210 are cubical or rectangular in shape while in a different example they may be circular in shape.

It is appreciated that the TSVs 210 goes through a top surface of the CMOS 190 die to a back surface of the CMOS 190 die. As such, once the CMOS 190 die is bonded to the MEMS die forming a monolithic die, the TSVs 210 positioned on the back side of the CMOS 190 die can be used for probing purposes and further the TSVs 210 positioned on the side of the CMOS 190 die may be used to allow the CMOS 190 die to electrically connect to an external circuitry (circuitry and/or electrical component positioned outside of the monolithic die). As such, the need to stagger the positioning of the CMOS 190 and the MEMS 160 die is eliminated. Moreover, a need to cut a portion of the MEMS 160 die after the monolithic die is eliminated because the CMOS 190 die can electrically connect to an external circuitry of the monolithic die using the TSVs 210 positioned on the periphery region 220.

Accordingly, the electrical connection for the CMOS 190 die is moved from its active side 188 (i.e., top surface facing the MEMS die) to a different side (e.g., periphery region 220 on the sides and/or the bottom surface). It is appreciated that the active side 188 of the CMOS 190 die is the surface that faces the other die within the monolithic die. For example, the active side 188 of the CMOS 190 die is the surface that faces the surface of the MEMS die 160. Thus, the CMOS 190 die may make electrical contact with circuitry external to the monolithic die (once the monolithic die comprising a MEMS die and the CMOS die is formed) without having to stagger the MEMS die with respect to the CMOS die or without having to remove a portion of the MEMS die.

It is appreciated that the embodiments are described with respect to electrical connection being a TSV for illustrative purposes and should not be construed as limiting the scope of the embodiments. For example, a wire bonding or flip chip connection positioned on the periphery region 220 (at the bottom of the CMOS die) or electrical connection on the side of the CMOS die may facilitate the electrical connection to the external circuitry. Regardless of the type of electrical connection used, moving the electrical connection from the active side 188 of the CMOS 190 die to a different side, e.g., sides, back side, etc., enables the monolithic die to be formed from two dice without having to stagger the two dice or without having to remove a portion of a die within the monolithic die.

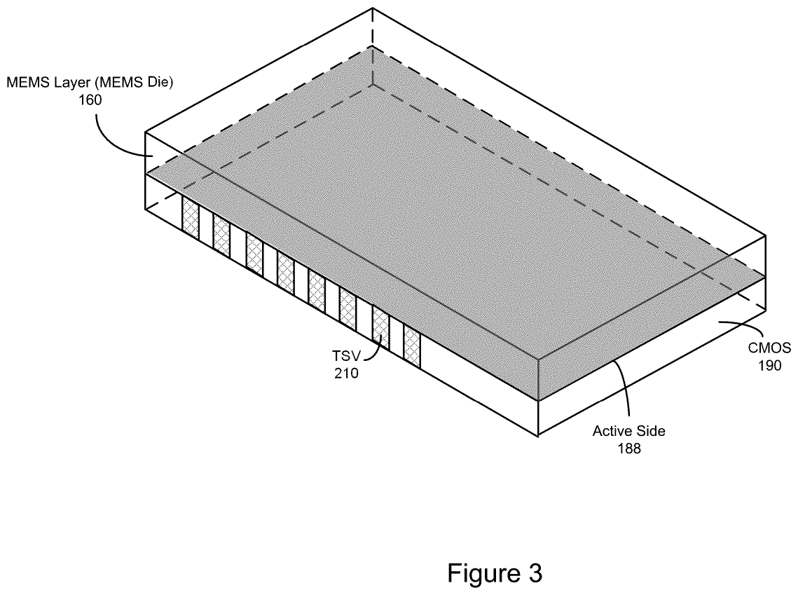

Referring now to FIG. 3, a fabricated monolithic die comprising a MEMS die 160 and a CMOS 190 die according to one aspect of the present embodiments is shown. The monolithic die is formed after the CMOS 190 die is coupled to the MEMS die 160, e.g., through eutectic bonding in one nonlimiting example. As illustrated, once a monolithic die is formed, the TSVs 210 positioned on the side of the CMOS 190 die are exposed and can enable the CMOS 190 die to make electrical contact with external circuitries. In this embodiment, the surface of the CMOS 190 die that faces the MEMS die 160 is the active side 188 of the CMOS 190 die. The sides of the CMOS 190 die and the bottom surface of the CMOS 190 die facing away from the MEMS die 160 are where electrical connections to external circuitries are formed to eliminate the need to stagger the two dice or to remove a portion of the top die to expose the bonding pad on the active side 188 (surface) of the CMOS 190 die.

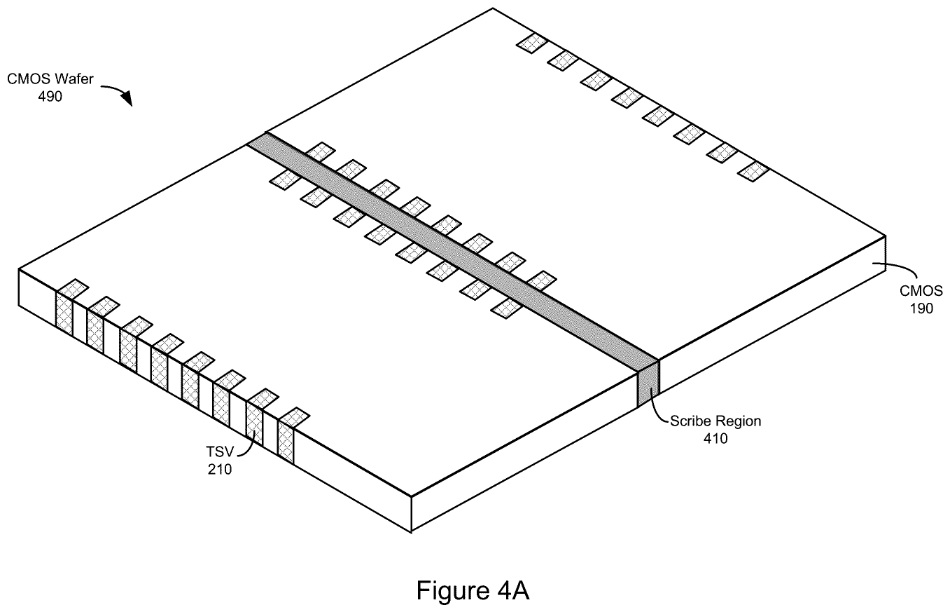

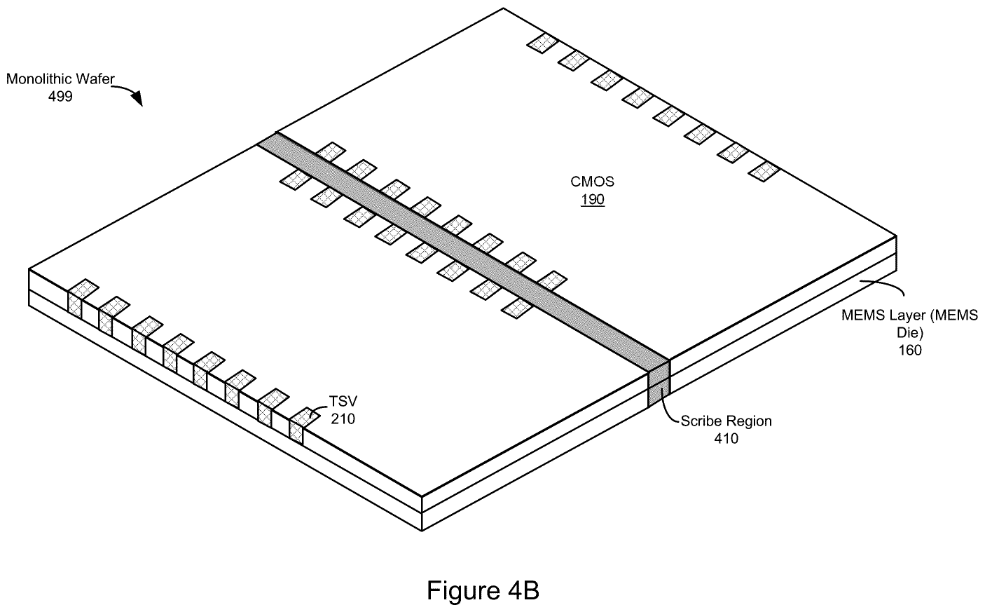

Referring now to FIG. 4A, a CMOS wafer 490 according to one aspect of the present embodiments is shown. The CMOS wafer 490 includes a plurality of CMOS 190 dice (only two are shown in this Figure for illustrative purposes). It is appreciated that the CMOS wafer 490 as illustrated includes two CMOS 190 dice, each with its respective TSVs 210. It is appreciated that one CMOS 190 dice may be positioned adjacent to one another and separated by a scribe region 410 that is positioned between their respective TSVs 210. Cutting through the scribe region 410 of the CMOS wafer 490 separates CMOS 190 dice from one another forming individual CMOS 190 die as shown in FIG. 2. The CMOS 190 die of FIG. 2 may be used with a MEMS die to form a monolithic die.

In some embodiments, the CMOS wafer 490 may be bonded (e.g., eutecticly bonded as described above) to a MEMS wafer that includes a plurality of MEMS layer (MEMS die 160), as shown in FIG. 4B to form a fabricated monolithic wafer 499. It is appreciated that cutting through the scribe region 410 forms individual monolithic dice, where each monolithic die includes a CMOS 190 die and a MEMS 160 die (e.g., eutecticly bonded together). As illustrated, cutting through the scribe region 410 exposes the TSVs 210 to an environment external to the monolithic die. As such, the TSVs 210 of the CMOS 190 die of the monolithic die may be used to make electrical contact with circuitry (e.g., electrical components) that are external (positioned outside) to the monolithic die.

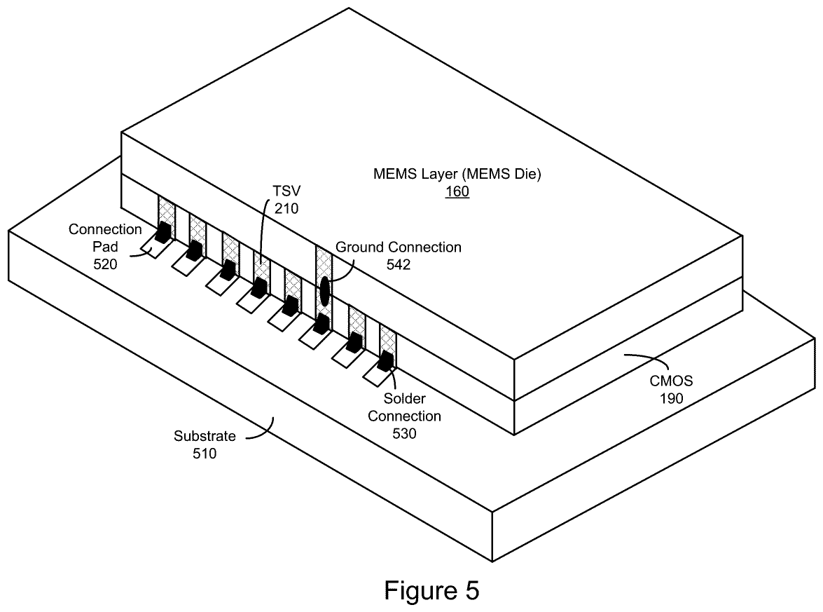

Referring now to FIG. 5, a fabricated monolithic die coupled to an external circuitry according to one aspect of the present embodiments is shown. In this nonlimiting example, the monolithic die comprising the MEMS die 160 and the CMOS 190 die may be electrically connected to the substrate 510 (circuitry external to the monolithic die). In this example, the substrate 510 may be a printed circuit board (PCB) with connection pads 520. The monolithic die may be positioned on the substrate 510 and a solder connection 530 may be deposited between the TSVs 210 and the connection pad 520 to electrically connect the CMOS 190 die of the monolithic die to the external circuitry (i.e., substrate 510). It is appreciated that the solder connection 530 may be formed using a jet solder ball bonding. For example, a micro-gun may be used to shoot melted material that once reaches the TSVs 210 and the connection pad 520 solidifies as the solder connection 530, thereby eliminating the need to use an oven used for wire bonding process or eliminating the need for vibration exposure that may adversely impact the performance of the MEMS die.

Some of the advantages of moving the electrical connection from the active side 188 to a different side on the CMOS 190 die include eliminating the need to use wire bonding which uses heat/ultrasound. As such, stress associated with application of heat, or stress associated with ultrasound impacting the resonance frequency of the MEMS die, etc., are eliminated. Moreover, bonding pads are no longer needed on the CMOS die, thereby achieving a smaller form factor and saving valuable chip area. It is appreciated that the monolithic die may be packaged and assembled as a regular lang grid array (LGA) or quad flat no-lead (QFN) package.

It is appreciated that in some embodiments the ground connection 542 may be formed from the MEMS die 160 to the CMOS 190 by electrically connecting the MEMS die 160 to one of the TSVs 210. Moreover, it is appreciated that by moving the electrical connection from the active side 188 to a different side on the CMOS 190 die, the need for the piano structure is eliminated, thereby also eliminating the need for a packing structure to be formed on the monolithic die because the MEMS die 160 can act as a packing structure for the CMOS 190. In other words, the monolithic die as formed can achieve a smaller footprint by eliminating the need for the packing structure.

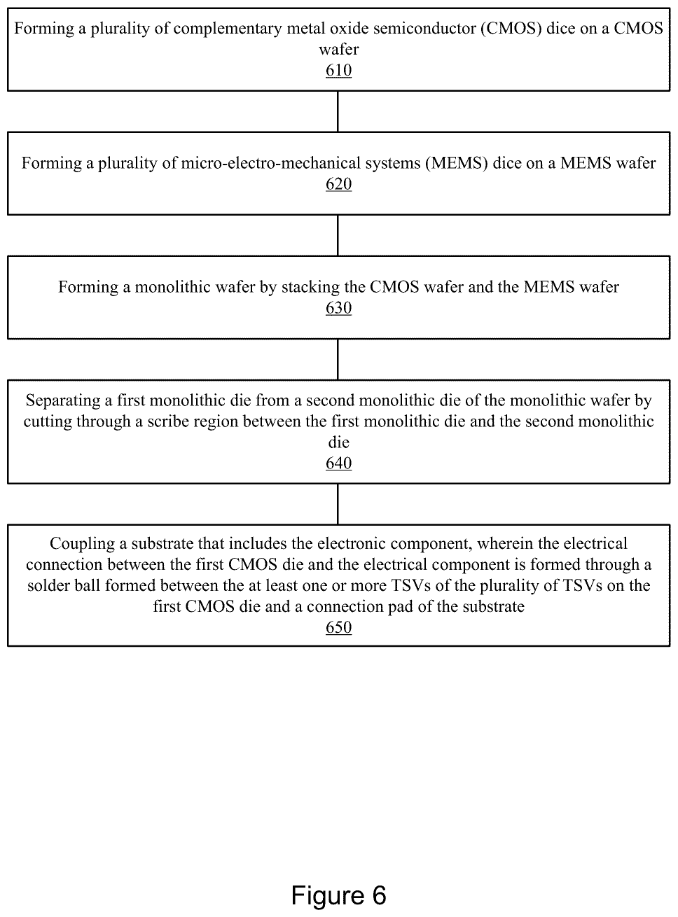

Referring now to FIG. 6, a method flow for fabricating a CMOS die according to one aspect of the present embodiments is shown. At step 610, a plurality of CMOS dice is formed on a CMOS wafer. It is appreciated that each CMOS die of the plurality of CMOS dice includes a plurality of TSVs (e.g., cube shaped, circular shaped, etc.) associated therewith and positioned on a periphery of its associated CMOS die. At step 620, a plurality of MEMS dice is formed on a MEMS wafer. At step 630, a monolithic wafer is formed by stacking the CMOS wafer and the MEMS wafer. It is appreciated that the monolithic wafer comprises a plurality of monolithic dice. Moreover, it is appreciated that each monolithic die of the plurality of monolithic dice comprises a CMOS die and a MEMS die that are stacked on top of one another forming a monolithic die (e.g., eutectic bonding the CMOS wafer to the MEMS wafer). At step 640, a first monolithic die is separated from a second monolithic die of the monolithic wafer by cutting through a scribe region between the first monolithic die and the second monolithic die. At step 650, a substrate that includes the electronic component is optionally coupled to the first monolithic die. The electrical connection between the first CMOS die and the electrical component is formed through a solder ball formed between the at least one or more TSVs of the plurality of TSVs on the first CMOS die and a connection pad of the substrate.

It is appreciated that the first monolithic die comprises a first MEMS die (first MEMS cap layer that is coupled to a first MEMS device layer) and a first CMOS die and wherein the second monolithic die comprises a second MEMS die and a second CMOS. It is appreciated that the first MEMS device layer comprises movable structures including a proof mass and that the first MEMS cap layer forms at least a cavity when coupled to the first MEMS device layer. The first MEMS die may be a sensor configured to measure gyro or acceleration. Moreover, it is appreciated that the separating exposes at least one or more TSVs of the plurality of TSVs of the first CMOS die to an environment outside of the first monolithic die. Furthermore, it is appreciated that the separating exposes at least one or more TSVs of the plurality of TSVs of the second CMOS die to the environment outside of the second monolithic die. It is appreciated that the at least one or more TSVs of the plurality of TSVs of the first CMOS is configured to facilitate electrical connection between the first CMOS die of the first monolithic die and an electronic component that is external to the first monolithic die. In some embodiments, the at least one or more TSVs of the plurality of TSVs of the second CMOS is configured to facilitate electrical connection between the second CMOS die of the second monolithic die and another electronic component that is separate from the second monolithic die and is positioned outside of the second monolithic die.

While the embodiments have been described and/or illustrated by means of particular examples, and while these embodiments and/or examples have been described in considerable detail, it is not the intention of the Applicants to restrict or in any way limit the scope of the embodiments to such detail. Additional adaptations and/or modifications of the embodiments may readily appear, and, in its broader aspects, the embodiments may encompass these adaptations and/or modifications. Accordingly, departures may be made from the foregoing embodiments and/or examples without departing from the scope of the concepts described herein. The implementations described above and other implementations are within the scope of the following claims.

What is claimed is:

1. A method comprising:
forming a plurality of complementary metal oxide semiconductor (CMOS) dice on a CMOS wafer, wherein each CMOS die of the plurality of CMOS dice includes a plurality of through silicon vias (TSVs) associated therewith and positioned on a periphery of its associated CMOS die;
forming a plurality of micro-electro-mechanical systems (MEMS) dice on a MEMS wafer;
forming a monolithic wafer by stacking the CMOS wafer and the MEMS wafer, wherein the monolithic wafer comprises a plurality of monolithic dice, wherein each monolithic die of the plurality of monolithic dice comprises a CMOS die and a MEMS die that are stacked on top of one another forming a monolithic die; and
separating a first monolithic die from a second monolithic die of the monolithic wafer by cutting through a scribe region between the first monolithic die and the second monolithic die,
wherein the first monolithic die comprises a first MEMS die and a first CMOS die and wherein the second monolithic die comprises a second MEMS die and a second CMOS die,
wherein the separating exposes at least one or more TSVs of the plurality of TSVs of the first CMOS die to an environment outside of the first monolithic die,
wherein the separating exposes at least one or more TSVs of the plurality of TSVs of the second CMOS die to the environment outside of the second monolithic die,
wherein the at least one or more TSVs of the plurality of TSVs of the first CMOS is configured to facilitate electrical connection between the first CMOS die of the first monolithic die and an electronic component that is external to the first monolithic die.

2. The method of claim 1, wherein the at least one or more TSVs of the plurality of TSVs of the second CMOS is configured to facilitate electrical connection between the second CMOS die of the second monolithic die and another electronic component that is separate from the second monolithic die and is positioned outside of the second monolithic die.

3. The method of claim 1, wherein the first MEMS die comprises a first MEMS cap layer that is coupled to a first MEMS device layer.

4. The method of claim 3, wherein the first MEMS device layer comprises movable structures including a proof mass.

5. The method of claim 3, wherein the first MEMS cap layer forms at least a cavity when coupled to the first MEMS device layer.

6. The method of claim 1, wherein the first MEMS die is a sensor for measuring gyro or acceleration.

7. The method of claim 1 further comprising coupling a substrate that includes the electronic component to the first monolithic die, wherein the electrical connection between the first CMOS die and the electrical component is formed through a solder ball formed between the at least one or more TSVs of the plurality of TSVs on the first CMOS die and a connection pad of the substrate.

8. The method of claim 1, wherein the forming the monolithic wafer includes eutectic bonding the CMOS wafer to the MEMS wafer.

9. The method of claim 1, wherein the plurality of TSVs formed on the periphery of associated CMOS die of the CMOS wafer is cube shaped.

10. The method of claim 1, wherein the plurality of TSVs formed on the periphery of associated CMOS die of the CMOS wafer is circular shaped.

11. A device comprising:
a first die; and
a second die,
wherein the first die and the second die are stacked and form a monolithic die, wherein a first side of the first die faces a first side of the second die,
wherein the second die comprises an electrical connection within its periphery and on a side other than the first side of the second die, wherein the electrical connection exposes the second die to an environment outside of the monolithic die, and wherein the electrical connection is configured to facilitate electrical connection between the second die of the monolithic die and an electronic component that is external to the monolithic die.

12. The device of claim 11, wherein the first die is a micro-electro-mechanical systems (MEMS) die and wherein the second die is a complementary metal oxide semiconductor (CMOS) die, and wherein the MEMS die comprises a MEMS cap layer that is coupled to a MEMS device layer.

13. The device of claim 12, wherein the MEMS device layer comprises movable structures including a proof mass.

14. The device of claim 12, wherein the MEMS cap layer forms at least a cavity when coupled to the MEMS device layer.

15. The device of claim 11, wherein the MEMS die is a sensor for measuring gyro or acceleration.

16. The device of claim 11 further comprising a substrate comprising the electronic component, wherein the electrical connection on the second die is a plurality of through silicon vias (TSVs), and wherein the electrical connection between the second die and the electrical component is formed through a solder ball formed between at least one TSV of the plurality of TSVs on the second die and a connection pad of the substrate.

17. The device of claim 16, wherein at least one TSV of the plurality of TSVs is cube shaped.

18. The device of claim 11, wherein the monolithic die is formed by eutectic bonding the first die to the second die.

19. A monolithic device comprising:
a micro-electro-mechanical systems (MEMS) die; and
a complementary metal oxide semiconductor (CMOS) die bonded to the MEMS die forming a single integrated die,
wherein the CMOS die comprises a plurality of through silicon vias (TSVs) positioned on an outer edge of the CMOS die and is exposed to an environment outside of the single integrated die, and
wherein the plurality of TSVs is configured to facilitate electrical connection between the CMOS die and an electronic component that is external to the single integrated die.

20. The monolithic device of claim 19, wherein the plurality of TSVs is cube shaped.
